(19) United States
(12) Patent Application Publication
(10) Pub. No.: US 2025/0107351 A1
(43) Pub. Date: Mar. 27, 2025

(54) SEMICONDUCTOR DEVICE, DISPLAY APPARATUS, PHOTOELECTRIC CONVERSION APPARATUS, AND ELECTRONIC DEVICE

(71) Applicant: CANON KABUSHIKI KAISHA, Tokyo (JP)

(72) Inventors: TETSUO TAKAHASHI, Kanagawa (JP); KOJI ISHIZUYA, Kanagawa (JP); EISUKE GOMMORI, Kanagawa (JP); RYO SATO, Kanagawa (JP); TAKAYUKI ITO, Kanagawa (JP); YOJIRO MATSUDA, Kanagawa (JP)

(21) Appl. No.: 18/896,457

(22) Filed: Sep. 25, 2024

(30) Foreign Application Priority Data
Sep. 25, 2023 (JP) 2023-161737

(51) Int. Cl. H10K 59/122; H10K 59/80

(52) U.S. Cl. CPC H10K 59/122; H10K 59/879

(57) ABSTRACT

A semiconductor device includes a first electrode disposed over an element substrate, an insulating layer covering an end of the first electrode, an organic layer disposed over the first electrode and the insulating layer, and a second electrode disposed over the organic layer. The insulating layer includes a step portion and a steeply inclined portion, and a distance from the step portion to a contact portion where the first electrode and the organic layer are in contact is greater than a distance from the step portion to the steeply inclined portion. In a cross section, a height of the steeply inclined portion is greater than a thickness from the first electrode to the first light-emitting layer in the contact portion, and a depth of the step portion is greater than the height of the steeply inclined portion and smaller than a thickness of the organic layer in the contact portion.

### BACKGROUND OF THE DISCLOSURE

### Field of the Disclosure

The present disclosure relates to, for example, a semiconductor device, a display apparatus, a photoelectric conversion apparatus, and an electronic device.

### Description of the Related Art

As a device using an organic layer, a semiconductor device including a light-emitting element or a photoelectric conversion element is discussed. An organic electroluminescent (EL) element (an organic light-emitting element) as an example of the light-emitting element is an element including an upper electrode, a lower electrode, and an organic layer disposed between the upper and lower electrodes. The organic EL element emits light by exciting an organic compound included in the organic layer. In recent years, a device including an organic light-emitting element draws attention.

In a semiconductor device including an organic light-emitting element, a plurality of light-emitting elements may include a common organic layer. In this configuration, the leakage of a current through the organic layer between adjacent light-emitting elements is likely to occur. A leakage current between light-emitting elements causes the emission of light from an unintended light-emitting element. For example, in a case where the semiconductor device is used in a display apparatus, the emission of light from an unintended light-emitting element narrows a color gamut indicating the representation performance of the display apparatus. In a single light-emitting element, in a case where a partial range of a continuous organic layer is to be caused to emit light, a leakage current causes the unintended emission of light.

Japanese Patent Application Laid-Open No. 2014-123527 discusses a light-emitting device including a tandem element in which a plurality of light-emitting units is laminated as an organic layer. The tandem element has an advantage in improving the light emission efficiency, whereas a leakage current between adjacent light-emitting elements is likely to be generated through a charge generation layer having high conductivity. Japanese Patent Application Laid-Open No. 2014-123527 discusses a method for providing a depression in a partition wall located between lower electrodes of light-emitting elements to prevent a leakage current between the light-emitting elements.

In the light-emitting elements discussed in Japanese Patent Application Laid-Open No. 2014-123527, the depth of the depression is greater than the thickness between an upper electrode and a lower electrode. Thus, the film thickness between the upper electrode and the lower electrode is likely to be thinned, and a leakage current between the upper electrode and the charge generation layer or between the charge generation layer and the lower electrode is likely to be generated. This may reduce the light emission efficiency or the gradation controllability.

### SUMMARY OF THE DISCLOSURE

The present disclosure is directed to providing a technique having an advantage in reducing a leakage current between elements and a leakage current between an upper electrode and a lower electrode in a semiconductor device.

According to an aspect of the present disclosure, a semiconductor device includes a first electrode disposed over an element substrate, an insulating layer that covers an end of the first electrode, an organic layer disposed over the first electrode and the insulating layer, and a second electrode disposed over the organic layer. The organic layer includes a first light-emitting layer, a charge transport layer disposed between the first electrode and the first light-emitting layer, and a charge generation layer disposed between the first light-emitting layer and the second electrode. The insulating layer includes a step portion and a steeply inclined portion. The steeply inclined portion is inclined with an angle between the steeply inclined portion and a parallel plane parallel to a lower surface of the first electrode being greater than 50°, and a distance from the step portion to a contact portion where the first electrode and the organic layer are in contact with each other is greater than a distance from the step portion to the steeply inclined portion. In a cross section through the element substrate, the first electrode, and the insulating layer, in a direction perpendicular to the parallel plane, a length of the steeply inclined portion is greater than a distance from the first electrode to the first light-emitting layer in the contact portion, and in the direction perpendicular to the parallel plane, a length of the step portion is greater than the length of the steeply inclined portion and smaller than a thickness of the organic layer in the contact portion.

Further features of the present disclosure will become apparent from the following description of exemplary embodiments with reference to the attached drawings.

### BRIEF DESCRIPTION OF THE DRAWINGS

FIG. 1 is a schematic cross-sectional view of an example of a part of a semiconductor device according to an exemplary embodiment.

FIG. 2 is a schematic plan view illustrating a part of the semiconductor device according to the exemplary embodiment.

FIG. 3 is a schematic plan view illustrating a part of the semiconductor device according to the exemplary embodiment.

FIG. 4 is a schematic cross-sectional view of a part of the semiconductor device according to the exemplary embodiment.

FIG. 5 is a diagram illustrating a vapor deposition simulation.

FIG. 6 is a diagram illustrating the vapor deposition simulation.

FIGS. 7A, 7B, and 7C are schematic cross-sectional views of examples of a step portion.

FIG. 8 is a ratio of a distance between ends of an insulating layer over two adjacent lower electrodes to a layer thickness of an organic layer in contact with the lower electrodes.

FIG. 9 is a diagram illustrating a relationship of chromaticity of red pixels.

FIG. 10 is a schematic cross-sectional view of an example of a part of a semiconductor device according to an exemplary embodiment.

FIG. 11 a schematic view illustrating an example of a display apparatus according to an exemplary embodiment.

FIG. 12A is a schematic view illustrating an example of an imaging apparatus according to the exemplary embodiment, and FIG. 12B is a schematic view illustrating an example of an electronic device according to the exemplary embodiment.

FIG. 13A is a schematic view illustrating an example of a display apparatus according to the exemplary embodiment, and FIG. 13B is a schematic view illustrating an example of a foldable display apparatus.

FIG. 14A is a schematic view illustrating an example of an illumination apparatus according to the exemplary embodiment, and FIG. 14B is a schematic view illustrating an example of an automobile including a lamp fitting for a vehicle according to the exemplary embodiment.

FIG. 15A is a schematic view illustrating an example of a wearable device according to the exemplary embodiment, and FIG. 15B is a schematic view illustrating an example of a wearable device according to the exemplary embodiment and a form in which the wearable device includes an imaging apparatus.

FIG. 16A is a schematic view illustrating an image forming apparatus according to an exemplary embodiment, and FIGS. 16B and 16C are schematic views illustrating forms in which a plurality of light-emitting units of an exposure light source is placed on a long substrate.

### DESCRIPTION OF THE EMBODIMENTS

Examples of specific exemplary embodiments of a semiconductor device, a display apparatus, a photoelectric conversion apparatus, and an electronic device according to the present disclosure will be described below with reference to the drawings. The dimensions, the materials, the shapes, and the relative arrangement of the components described below do not limit the scope of the present disclosure to them only, unless specifically stated otherwise. In the following description and the drawings, components common to a plurality of drawings are designated by common signs. Accordingly, the common components are described with reference to the plurality of drawings, and the description of the components designated by the common signs is appropriately omitted.

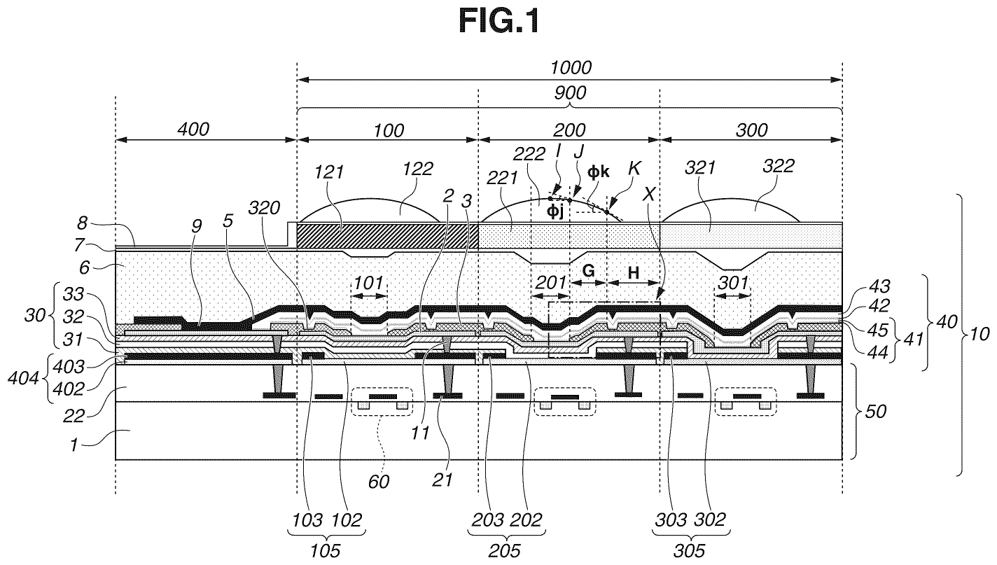

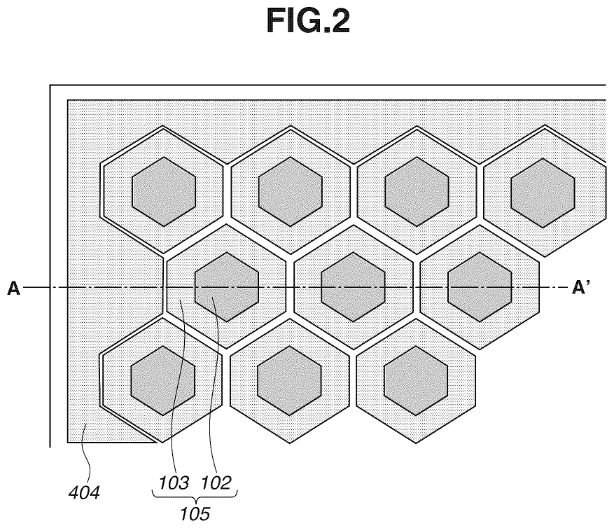

With reference to FIGS. 1 to 9, an example of the configuration of a semiconductor device is described. FIG. 1 is a schematic cross-sectional view of a part of a semiconductor device according to a first exemplary embodiment. FIG. 2 is a schematic plan view of a part of the semiconductor device according to the present exemplary embodiment. FIG. 1 is a schematic cross-sectional view along a line segment A-A′ in the semiconductor device illustrated in FIG. 2.

In the specification, “up” and “down” refer to the up and down directions in FIG. 1. Among main surfaces of a substrate 1, a surface on which a lower electrode 2 is disposed is referred to as “an upper surface of the substrate 1”. A surface on the substrate 1 side of the lower electrode 2 is referred to as “a lower surface of the lower electrode 2”. Thus, for example, in a case where a plug for connecting to another wire is connected to the lower surface of the lower electrode 2, an approximately flat surface portion except for this plug portion is the lower surface.

In the specification, the distance between a member A and a member B in a certain direction refers to the distance between the end of the member A closest to the member B and the end of the member B closest to the member A in the certain direction.

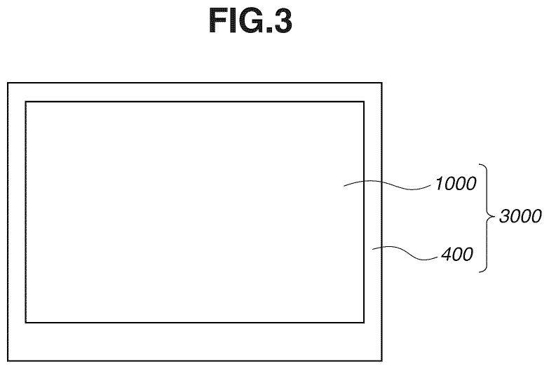

FIG. 3 is a schematic plan view according to the first exemplary embodiment of the present disclosure. A display region 1000 is a region which is provided in a display apparatus 3000 and where pixels that emit light are arranged. FIG. 2 is an enlarged view of a part of the display region 1000 in FIG. 3.

The details of an example of the semiconductor device according to the present exemplary embodiment are described below. A semiconductor device 10 includes a plurality of organic light-emitting elements 900. For example, the plurality of the organic light-emitting elements 900 includes a first organic light-emitting element 100, a second organic light-emitting element 200, and a third organic light-emitting element 300 illustrated in FIG. 1.

On a substrate 1, switching elements 60 such as transistors, wires 21, and an interlayer insulating layer 22 may be formed. In the specification, a portion from the substrate 1 to the interlayer insulating layer 22 is referred to as an “element substrate 50”. That is, for example, the element substrate 50 includes the switching elements 60, the wires 21, and the interlayer insulating layer 22. FIG. 1 illustrates an example where transistors are disposed as the switching elements 60. The transistors are electrically connected to the organic light-emitting element 900 (not illustrated).

For example, in a case where the semiconductor device 10 is a display apparatus, the semiconductor device 10 includes a plurality of pixels. Each of the pixels may include an organic light-emitting element 900 and transistors electrically connected to lower electrodes 2 of the organic light-emitting element 900. The transistors control the driving of the organic light-emitting element 900, whereby it is possible to form an image on a display unit of the display apparatus.

The semiconductor device 10 according to the present exemplary embodiment includes a lower electrode 2 (a first electrode) disposed over the element substrate 50, an insulating layer 3 that covers an end of the lower electrode 2, an organic layer 40 disposed over the lower electrode 2 and the insulating layer 3, and an upper electrode 5 (a second electrode) disposed over the organic layer 40. The organic layer 40 includes a first light-emitting layer 45, a lower first organic layer 44 disposed between the lower electrode 2 and the first light-emitting layer 45 and including a charge transport layer, and a charge generation layer 42 disposed between the first light-emitting layer 45 and the upper electrode 5.

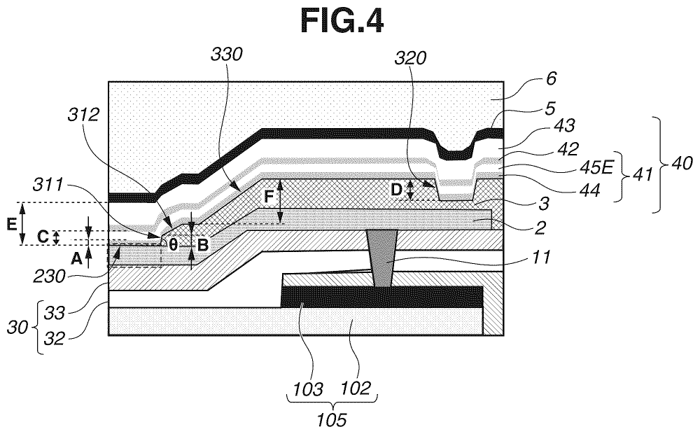

Although the details will be described below, as illustrated in FIG. 4, the insulating layer 3 according to the present exemplary embodiment includes a steeply inclined portion 311 and a step portion 320. The angle between the surface of the steeply inclined portion 311 and a plane (a parallel plane) parallel to a lower surface of the lower electrode 2 is greater than 50°. The distance from the step portion 320 to a contact portion 230 where the lower electrode 2 and the organic layer 40 are in contact with each other is greater than the distance from the step portion 320 to the steeply inclined portion 311.

In a cross section through the element substrate 50, the lower electrode 2, and the insulating layer 3, the length of the steeply inclined portion 311 in a direction perpendicular to the parallel plane is greater than the thickness from the lower electrode 2 to the first light-emitting layer 45 in the contact portion 230. In the cross section, the length of the step portion 320 in the direction perpendicular to the parallel plane is greater than the length of the steeply inclined portion 311 in the direction perpendicular to the parallel plane and smaller than the thickness of the organic layer 40 in the contact portion 230.

The details of the semiconductor device 10 according to the present exemplary embodiment are described below. The substrate 1 is formed of a material capable of supporting the lower electrode 2, the organic layer 40, and the upper electrode 5. As the material, glass, plastic, or silicon is suitable.

It is desirable that the material of the lower electrode 2 of the first organic light-emitting element 100 have light transmission properties in terms of the light emission efficiency. Specifically, a thin film of a transparent conductive oxide such as indium tin oxide (ITO) or indium zinc oxide (IZO), a metal such as aluminum (Al), silver (Ag), or platinum (Pt), or an alloy of Al, Ag, or Pt can be used. The lower electrodes 2 of the first organic light-emitting element 100, the second organic light-emitting element 200, and the third organic light-emitting element 300 are electrically separated from each other. To optimize optical interference, the film thicknesses of the lower electrodes 2 of the first organic light-emitting element 100, the second organic light-emitting element 200, and the third organic light-emitting element 300 may be different from each other.

The organic layer 40 is placed over the lower electrode 2 of the first organic light-emitting element 100. The organic layer 40 is a layer including at least a light-emitting layer, and may include a plurality of layers.

The organic layer 40 emits light from the light-emitting layer by a hole injected from an anode and an electron injected from a cathode recombining in the light-emitting layer. The light-emitting layer may include a single layer or a plurality of layers. Any of the light-emitting layers can have a red light-emitting material, a green light-emitting material, or a blue light-emitting material, and white light can also be obtained by mixing these light-emitting colors. Any of the light-emitting layers may have light-emitting materials in a relationship where the light-emitting materials are complementary colors, such as a blue light-emitting material and a yellow light-emitting material.

The organic layer 40 may include a hole transport layer, a light-emitting layer, and an electron transport layer. As the material of the organic layer 40, an appropriate material can be selected in terms of each of the light emission efficiency, the driving life, and optical interference.

The hole transport layer may function as an electron block layer or a hole injection layer, or may have a laminated structure of a hole injection layer, a hole transport layer, and an electron block layer. The light-emitting layer may have a laminated structure of light-emitting layers that emit light of different colors, or may be a mixed layer obtained by mixing light-emitting dopants that emit light of different colors.

The electron transport layer may function as a hole block layer or an electron injection layer, or may have a laminated structure of an electron injection layer, an electron transport layer, and a hole block layer.

A region between an electrode as the anode between the upper electrode 5 and the lower electrode 2 and the light-emitting layer is the hole transport layer, and a region between an electrode as the cathode between the upper electrode 5 and the lower electrode 2 and the light-emitting layer is the electron transport layer. The hole transport layer and the electron transport layer are collectively referred to as a “charge transport layer”.

It is desirable that the hole transport layer be in contact with the lower electrode 2. In a case where the hole transport layer has a higher mobility than that of the electron transport layer, a leakage current between lower electrodes 2 is likely to flow. Thus, it is possible to more greatly achieve the effects of the present exemplary embodiment.

The organic layer 40 may be of a tandem type including a charge generation layer 42, a first organic layer 41 below the charge generation layer 42, and a second organic layer 43 over the charge generation layer 42. Each of the first organic layer 41 and the second organic layer 43 includes a light-emitting layer. In a case where there is a plurality of charge generation layers 42, an organic layer below the lowermost charge generation layer 42 is the first organic layer 41. As described below, a charge transport layer such as a hole transport layer or an electron transport layer may be formed between the charge generation layer 42 and each of the light-emitting layers.

The charge generation layer 42 is a layer that includes an electron-donating material and an electron-accepting material and generates charges. The electron-donating material is a material that gives an electron, and the electron-accepting material is a material that receives the electron. This generates positive and negative charges in the charge generation layer 42, and therefore, the charge generation layer 42 can supply positive or negative charges to the layers over and below the charge generation layer 42. The electron-donating material may be an alkali metal such as lithium or cesium. For example, the electron-donating material may be lithium fluoride, a lithium complex, cesium carbonate, or a cesium complex. In this case, the electron-donating material may be included with a reducing material such as aluminum, magnesium, or calcium, thereby achieving electron-donating properties.

The electron-donating material may be a hole-transporting material. As the hole-transporting material, a triarylamine derivative, a phenylenediamine derivative, a triazole derivative, an oxadiazole derivative, an imidazole derivative, a pyrazoline derivative, a pyrazolone derivative, an oxazole derivative, a fluorenone derivative, a hydrazone derivative, or a stilbene derivative can be used. As the hole-transporting material, an organic compound such as a phthalocyanine derivative, a porphyrin derivative, poly(vinylcarbazole), poly(silylene), poly(thiophene), or a conductive polymer can be used.

The electron-donating material may be included in an electron-transporting material. As the electron-transporting material, an oxadiazole derivative, an oxazole derivative, a thiazole derivative, a thiadiazole derivative, or a pyrazine derivative can be used. As the electron-transporting material, an organic compound such as a triazole derivative, a triazine derivative, a perylene derivative, a quinoline derivative, a quinoxaline derivative, a fluorenone derivative, an anthrone derivative, a phenanthroline derivative, or an organic metal complex can be used.

The electron-accepting material may be an inorganic substance such as a transition metal oxide, e.g., molybdenum oxide, or a hexaazatriphenylene derivative. The electron-accepting material may be an organic substance such as [dipyrazino [2,3-f: 2′,3′-h] quinoxaline-2,3,6,7,10,11-hexacarbonitrile]. The charge generation layer 42 may be a layer including the electron-accepting material and the electron-donating material in mixture, or may be a layer obtained by laminating a layer including the electron-donating material and a layer including the electron-accepting material.

The organic layer 40 can be formed by the following method.

An organic layer included in a light-emitting element according to the present exemplary embodiment can be formed using a vacuum vapor deposition method, an ionized vapor deposition method, or a sputtering or plasma dry process. Instead of the dry process, a wet process for forming the layer by dissolving a material into an appropriate solvent and performing a known application method (e.g., spin coating, dipping, a casting method, a Langmuir-Blodgett (LB) method, or an inkjet method) can also be used.

If the layer is formed by the vacuum vapor deposition method or the solution application method, crystallization is less likely to occur, and the stability over time is excellent. In a case where the film is formed by the application method, the film can also be formed in combination with an appropriate binder resin.

Examples of the binder resin include a polyvinyl carbazole resin, a polycarbonate resin, a polyester resin, an acrylonitrile butadiene styrene (ABS) resin, an acrylic resin, a polyimide resin, a phenolic resin, an epoxy resin, a silicon resin, and a urea resin. The above resins are merely examples, and the binder resin is not limited to these.

One type of these binder resins may be used alone as a homopolymer or a copolymer, or two or more types of these binder resins may be used in mixture. Further, an additive such as a known plasticizer, a known antioxidant, or a known ultraviolet absorber may be used in combination, where necessary.

The organic layer 40 is placed between the lower electrode 2 and the insulating layer 3, and the upper electrode 5. The organic layer 40 may be continuously formed over the element substrate 50 and shared by a plurality of organic light-emitting elements 900. That is, a single organic layer 40 may be shared by a plurality of organic light-emitting elements 900. The organic layer 40 may be integrally formed on the entire surface of the display region 1000 where an image of a light-emitting device is displayed.

The organic layer 40 may be placed over the lower electrode 2 of the first organic light-emitting element 100, the lower electrode 2 of the second organic light-emitting element 200, and the lower electrode 2 of the third organic light-emitting element 300. The entirety or a part of the organic layer 40 of the first organic light-emitting element 100, the second organic light-emitting element 200, and the third organic light-emitting element 300 may be patterned with respect to each element. The organic layer 40 may be located in an outer peripheral region on the outer periphery of the display region 1000.

The upper electrode 5 is placed over the organic layer 40 of the first organic light-emitting element 100 and has translucency. The upper electrode 5 may be a semi-transmissive material having the properties of transmitting a part of light reaching the surface of the upper electrode 5, and also reflecting the other part of the light (i.e., semi-transmission/reflection properties). As a material forming the upper electrode 5, a transparent conductive oxide such as ITO or IZO, a single-component metal such as aluminum, silver, or gold, an alkali metal such as lithium or cesium, or an alkaline earth metal such as magnesium, calcium, or barium can be used. As the material forming the upper electrode 5, for example, a semi-transmissive material composed of an alloy material including any of these metal materials may be used. It is particularly desirable that the semi-transmissive material be an alloy having magnesium or silver as a main component. The upper electrode 5 may have a laminated configuration of the over materials so long as the upper electrode 5 has desirable transmittance.

In a case where the semiconductor device 10 further includes the second organic light-emitting element 200 and the third organic light-emitting element 300, the upper electrode 5 may be disposed over the organic layer 40 of the first organic light-emitting element 100, the organic layer 40 of the second organic light-emitting element 200, and the organic layer 40 of the third organic light-emitting element 300. Similarly to the organic layer 40, the upper electrode 5 may be integrally formed on the entire surface of the display region 1000. The upper electrode 5 may be formed in an outer peripheral region on the outer periphery of the display region 1000.

In the present exemplary embodiment, the lower electrode 2 may be the anode, and the upper electrode 5 may be the cathode. The lower electrode 2 may be the cathode, and the upper electrode 5 may be the anode.

In the semiconductor device 10 according to the present exemplary embodiment, the insulating layer 3 may be provided in outer peripheral portions of the lower electrodes 2 of each organic light-emitting element 900. That is, the insulating layer 3 includes opening portions through which parts of the lower electrodes 2 are exposed. The insulating layer 3 is formed so that a light-emitting region 101 (a first light-emitting region), a light-emitting region 201 (a second light-emitting region), and a light-emitting region 301 (a third light-emitting region) accurately have desired shapes. In a case where the insulating layer 3 is not provided, the light-emitting regions 101, 201, and 301 are defined by the shapes of the lower electrodes 2. The insulating layer 3 is formed of an inorganic material such as silicon nitride (SiN), silicon oxynitride (SiON), or silicon oxide (SiO). The insulating layer 3 can be formed using a known technique such as a sputtering method or a chemical vapor deposition method (CVD method). The insulating layer 3 can also be formed using an organic material such as acrylic resin or polyimide resin.

A reflection portion 105 (a first reflection portion) includes a reflection layer 102 (a first reflection layer) and a conductive layer 103 (a first conductive layer). A reflection portion 205 (a second reflection portion) includes a reflection layer 202 (a second reflection layer) and a conductive layer 203 (a second conductive layer). A reflection portion 305 (a third reflection portion) includes a reflection portion 203 (a third reflection layer) and a conductive layer 303 (a third conductive layer).

The conductive layer 103 (the first conductive layer), the conductive layer 203 (the second conductive layer), and the conductive layer 303 are disposed over the reflection layers 102, 202, and 203, respectively, and function as electrolytic corrosion prevention layers.

The conductive layer 103 of the first reflection portion 105 may include an opening so that the reflection layer 102 is exposed in at least a part of a region of the first reflection portion 105 that the first light-emitting region 101 overlaps in a planar view. The conductive layer 103 includes the opening, whereby light emitted from the first organic light-emitting element 100 passes through the lower electrode 2 and is reflected by the reflection layer 102. Thus, it is possible to efficiently extract the light to the exit surface side.

In terms of an improvement in the light emission efficiency, it is desirable that the size of the opening of the conductive layer 103 be greater than or equal to the size of the first light-emitting region 101.

The light reflected by the reflection layer 102 is extracted through the upper electrode 5 to the light exit side. Thus, the semiconductor device 10 according to the present exemplary embodiment can obtain properties having high light emission efficiency. “The light exit side” refers to the direction of the upper electrode 5 with respect to the lower electrode 2.

A similar configuration applies to the second reflection portion 205 and the third reflection portion 305, and therefore, the following description is given using the first light-emitting region 101 and the first reflection portion 105 as examples.

F For example, it is desirable to select the reflection layer 102 from Ag or Al, which has a high reflectance. It is desirable to select the conductive layer 103 from cobalt (Co), molybdenum (Mo), Pt, tantalum (Ta), titanium (Ti), titanium nitride (TiN), or tungsten (W). Each of the reflection layer 102 and the conductive layer 103 may be an alloy or a compound. As a particularly suitable combination, for example, the reflection layer 102 is composed of a material having Al as a main component, and the conductive layer 103 is composed of a material having Ti or TiN as a main component. It is further desirable that the reflection layer 102 have Al as a main component and contain copper (Cu). It is desirable that the conductive layer 103 have TiN as a main component. On the substrate 1 side of the first reflection portion 105, a barrier metal such as Ti or TiN may be provided.

The reflection layer 102 and the conductive layer 103 can be formed by a known film formation technique such as a sputtering method, a CVD method, or an atomic layer deposition (ALD) method. After a film of a material having a high reflectance is formed on the substrate 1, the reflection layer 102 can be simultaneously formed of the same material as a main component by patterning the reflection layer 102 by a known etching process. After a film of a material is formed on the substrate 1, the conductive layer 103 can also be simultaneously formed of the same material as a main component by patterning the conductive layer 103 by a known etching process.

The opening portion of the conductive layer 103 provided in the first reflection portion 105 can be formed by removing the conductive layer 103 by a known etching process.

In the present exemplary embodiment, the semiconductor device 10 includes an optical interference layer 30 between the first reflection portion 105 and the lower electrode 2. The thickness of the optical interference layer 30 is adjusted, whereby it is possible to optimize the optical distance between a light-emitting layer and the reflection layer 102 of the first organic light-emitting element 100. Thus, it is possible to improve the light emission efficiency using optical interference. The optical interference layer 30 may be a single layer, or may have a laminated configuration of a plurality of layers.

In the present exemplary embodiment, the display region 1000 may include a plurality of organic light-emitting elements 900 such as the second organic light-emitting element 200 and the third organic light-emitting element 300 in addition to the first organic light-emitting element 100. Similarly to the first organic light-emitting element 100, each of the second organic light-emitting element 200 and the third organic light-emitting element 300 also includes an organic layer 40 at least including a light-emitting layer between a lower electrode 2 and an upper electrode 5. Further, the second organic light-emitting element 200 and the third organic light-emitting element 300 also include a second reflection portion 205 and a third reflection portion 305, respectively, on the substrate 1 side of the lower electrodes 2.

Similarly to the first reflection portion 105, the second reflection portion 205 includes the reflection layer 202 in at least a part of a region of the second reflection portion 205 that the second light-emitting region 201 overlaps in the planar view.

Similarly to the first reflection portion 105 and the second reflection portion 205, the third reflection portion 305 includes the reflection layer 302 in at least a part of a region of the third reflection portion 305 that the third light-emitting region 301 overlaps in the planar view.

Each of the second organic light-emitting element 200 and the third organic light-emitting element 300 may also include an optical interference layer 30.

It is possible to adjust the colors of light emitted from the first organic light-emitting element 100, the second organic light-emitting element 200, and the third organic light-emitting element 300 by differentiating the thicknesses of the optical interference layers 30 of the respective organic light-emitting elements. Each optical interference layer 30 can also have a laminated configuration of a plurality of layers.

For example, in a case where the optical interference layers 30 are made thinner in order of the first organic light-emitting element 100, the second organic light-emitting element 200, and the third organic light-emitting element 300, a first optical interference layer 31, a second optical interference layer 32, and a third optical interference layer 33 can be provided over the first reflection portion 105. The second optical interference layer 32 and the third optical interference layer 33 can be provided over the second reflection portion 205, and the third optical interference layer 33 can be provided over the third reflection portion 305.

It is desirable that each of the optical interference layers 30 be composed of a transparent material. For example, it is desirable that each of the optical interference layers 30 be composed of SiO, SiN, or SiON. As the formation technique, a known technique such as a sputtering method, a CVD method, or an ALD method can be used.

It is desirable to adjust the colors of light emitted from the first organic light-emitting element 100, the second organic light-emitting element 200, and the third organic light-emitting element 300 by differentiating the thicknesses of the optical interference layers 30 of the respective organic light-emitting elements as illustrated in FIG. 1. Consequently, it is possible to increase the light emission efficiency of the organic light-emitting elements of the respective colors. In the form in which the thicknesses of the optical interference layers 30 of the organic light-emitting elements are differentiated, unevenness on the surface of the insulating layer 3 is likely to be large. Thus, a leakage current between the lower electrode 2 and the charge generation layer 42 or the charge generation layer 42 and the upper electrode 5 is likely to be generated. Thus, it is easy to greatly achieve the effects of the present exemplary embodiment.

Although FIG. 1 illustrates an example where the lower electrode 2 and the reflection layer 102 are electrically connected together, the semiconductor device 10 is not limited to this. For example, the semiconductor device 10 may include a pixel contact region insulated from the reflection portion 105 and electrically connected to the lower electrode 2. Consequently, the first organic light-emitting element 100 can apply a current through the pixel contact region. As the pixel contact region, a wiring layer and the conductive layer 103 may be used.

In FIG. 1, the first organic light-emitting element 100 can apply a current through the reflection portion 105.

Further, also in a region where the second organic light-emitting element 200 is disposed and a region where the third organic light-emitting element 300, the semiconductor device 10 can include the reflection portion 205 and the reflection portion 305 having similar configurations, respectively.

In a case where the optical interference layer 30 is provided, a plug 11 is provided in the optical interference layer 30, and a conductive material is disposed in the plug 11, whereby it is possible to electrically connect the lower electrode 2 and a pixel contact region 115. The conductive material in the plug 11 may be the same material as that of the lower electrode 2.

As the conductive material provided in the plug 11, a known conductive material such as W, Ti, or TiN can be used. The lower electrode 2 and the reflection portion 105 may be in contact with each other through the plug 11. It is desirable that a portion of the reflection portion 105 in contact with the plug 11 may be the conductive layer 103 in terms of electrolytic corrosion prevention.

FIG. 2 is a plan view illustrating an example of a part of the semiconductor device 10 including the reflection portions 105, 205, and 305 according to the present exemplary embodiment. In a case where the reflection portion 105 and the lower electrode 2 are in direct contact with each other, it is desirable that the combination of the conductive layer 103 and the lower electrode 2 be less likely to cause galvanic corrosion. For example, it is desirable that the conductive layer 103 be formed of a material having TiN as a main component, and the lower electrode 2 may be ITO or IZO.

For example, the insulating layer 3 includes a groove as the step portion 320. For example, the step portion 320 can be patterned by etching the insulating layer 3. The step portion 320 may be disposed around an opening of the insulating layer 3.

A protection layer 6 can be composed of a material having low permeability to oxygen or moisture from outside, such as silicon nitride, silicon oxynitride, aluminum oxide, silicon oxide, or titanium oxide. For example, the silicon nitride and the silicon oxynitride may be formed using a CVD method. On the other hand, the aluminum oxide, the silicon oxide, and the titanium oxide can be formed using an atomic layer deposition method (ALD method).

The combination of the constituent material of the protection layer 6 and the method for manufacturing the protection layer 6 is not limited to the above example. The protection layer 6 may be manufactured taking into account the thickness of the layer to be formed and the time required for the formation. The protection layer 6 may have a single layer structure, or may have a laminated structure so long as the protection layer 6 transmits light passing through the upper electrode 5 and has sufficient moisture blocking properties.

Color filters 121, 221, and 321 are formed over the protection layer 6. The color filters 121, 221, and 321 may be in contact with each other as in the color filters 121 and 221 and the color filters 221 and 321 illustrated in FIG. 1. A color filter of a certain color may be placed on top of a color filter of another color. A planarization layer 7 may be placed below the color filters 121, 221, and 321, or a planarization layer 8 may be placed over the color filters 121, 221, and 321.

As illustrated in FIG. 1, microlenses 122, 222, and 322 may be placed over the planarization layer 8.

### (Regarding Steeply Inclined Portion and Step Portion of Insulating Layer)

FIG. 4 is an enlarged view of a portion X surrounded by a dotted line in FIG. 1 in the semiconductor device 10. In a cross section through the element substrate 50, the insulating layer 3, and the organic layer 40, the insulating layer 3 includes the steeply inclined portion 311. The steeply inclined portion 311 is a portion of the insulating layer 3 where an angle of inclination θ of the surface of the portion to the parallel plane parallel to the lower surface of the lower electrode 2 is greater than 50°.

An example is illustrated where the surface of the steeply inclined portion 311 is inclined to the parallel plane at an angle greater than 50°. Although FIG. 4 illustrates an example where each of the steeply inclined portion 311 and a gently inclined portion 312 has a constant angle of inclination, the angle of inclination may change in each inclined portion. For example, in a case where the angle of inclination continuously changes over the steeply inclined portion 311 and the gently inclined portion 312, a portion where the angle of inclination is 50° is the boundary between the steeply inclined portion 311 and the gently inclined portion 312.

FIG. 4 illustrates an example where the organic layer 40 includes the first organic layer 41, the charge generation layer 42, and the second organic layer 43.

The first organic layer 41 includes a lower first organic layer 44 including a charge transport layer, and an upper first organic layer 45. The upper first organic layer 45E includes a first light-emitting layer as the lowermost layer. That is, the boundary between the lower first organic layer 44 and the upper first organic layer 45E is a lower surface of the first light-emitting layer. The second organic layer 43 includes a second light-emitting layer.

Although FIG. 4 illustrates an example where only the charge transport layer is provided as the lower first organic layer 44, the lower first organic layer 44 may include either one or more of a charge generation layer and a charge block layer in addition to the charge transport layer. Each of the charge generation layer, the charge transport layer, and the charge block layer included in the lower first organic layer 44 may be a single layer, or may be a plurality of layers.

The upper first organic layer 45E may also include any one or more of a charge transport layer, a charge generation layer, and a charge block layer. Each of the charge generation layer, the charge transport layer, and the charge block layer included in the upper first organic layer 45E may be a single layer, or may be a plurality of layers.

The second organic layer 43 may include any one or more of a charge transport layer, a charge generation layer, and a charge block layer in addition to the light-emitting layer. Each of the charge generation layer, the charge transport layer, and the charge block layer included in the second organic layer 43 may be a single layer, or may be a plurality of layers.

In the present exemplary embodiment, a portion where an upper surface of the lower electrode 2 is in contact with the organic layer 40 is a contact portion 230. Although FIG. 4 illustrates an example where the contact portion 230 is uniformly flat, the contact portion 230 may include a non-flat portion by removing a part of the lower electrode 2 along a side surface of the insulating layer 3. The flat portion is a portion approximately parallel to the substrate 1 and is a portion where the angle of inclination is substantially 0°.

A portion where the lower electrode 2 and the organic layer 40 are in contact with each other is the contact portion 230. The thickness from the lower electrode 2 to the first light-emitting layer in the contact portion 230 may be the length from the lower electrode 2 to the first light-emitting layer in the direction perpendicular to the plane parallel to the lower surface of the lower electrode 2 over a flat portion of the upper surface of the lower electrode 2 in the contact portion 230. Similarly, the thickness from the lower electrode 2 to the charge generation layer 42 or the thickness of the organic layer 40 in the contact portion 230 may be the length from the lower electrode 2 to the charge generation layer 42 or the length of the organic layer 40 in the direction perpendicular to the plane parallel to the lower surface of the lower electrode 2 over the flat portion of the upper surface of the lower electrode 2 in the contact portion 230.

For example, in a case where the organic layer 40 includes a charge transport layer, the charge transport layer has a high charge mobility, and therefore, the organic layer 40 can efficiently transport charges from an electrode to a light-emitting layer. On the other hand, in a case where the charge transport layer is connected between adjacent light-emitting elements 900, charges may move between the light-emitting elements 900, and a leakage current may be generated. A leakage current may cause the emission of light from an unintended light-emitting element 900.

Accordingly, in a portion of a light-emitting element 900 that does not originally contribute to the emission of light (a portion between adjacent organic light-emitting elements 900), a portion having a small film thickness is provided in a layer having high charge transport properties, such as a charge transport layer, whereby it is possible to prevent the movement of charges in the layer and prevent a leakage current.

Similarly, the charge generation layer 42 also includes a portion having a small film thickness between adjacent organic light-emitting elements, whereby it is possible to prevent a leakage current between the adjacent organic light-emitting elements.

In the semiconductor device 10 according to the present exemplary embodiment, in the direction perpendicular to the plane parallel to the lower surface of the lower electrode 2, a length B of the steeply inclined portion 311 is greater than a distance A from the lower electrode 2 to the first light-emitting layer 45 in the contact portion 230 where the lower first organic layer 44 is in contact with the lower electrode 2. The distance A from the lower electrode 2 to the first light-emitting layer 45 in the contact portion 230 where the lower first organic layer 44 is in contact with the lower electrode 2 matches the thickness of the lower first organic layer 44 here. Consequently, the lower first organic layer 44 including the charge transport layer is thinned along the steeply inclined portion 311. Thus, it is possible to prevent charges from being transported to a portion located in the direction of the step portion 320 from the steeply inclined portion 311 in FIG. 4. Thus, it is possible to prevent a leakage current between adjacent organic light-emitting elements.

If, on the other hand, the distance A from the lower electrode 2 to the first light-emitting layer 45 in the contact portion 230 is greater than the length B of the steeply inclined portion 311, the steeply inclined portion 311 may be buried in the lower first organic layer 44, and the thickness of the lower first organic layer 44 on the steeply inclined portion 311 may not be sufficiently small. In this case, the lower first organic layer 44 includes a layer having high charge transport properties, such as the charge transport layer, and therefore, charges are likely to be transported to also a portion located in the direction of the step portion 320 from the steeply inclined portion 311 in FIG. 4. In the present exemplary embodiment, in the direction perpendicular to the plane parallel to the lower surface of the lower electrode 2, the length B of the steeply inclined portion 311 is smaller than a distance C from the lower electrode 2 to the charge generation layer 42 (the thickness of the first organic layer 41) in the contact portion 230 where the organic layer 40 is in contact with the lower electrode 2. Consequently, the steeply inclined portion 311 is buried in the first organic layer 41, and therefore, the first organic layer 41 does not become too thin along the steeply inclined portion 311. Thus, it is possible to prevent a current leakage between the lower electrode 2 and the charge generation layer 42.

If a leakage current flows between the lower electrode 2 and the charge generation layer 42, the light emission efficiency may decrease. In the semiconductor device 10 according to the present exemplary embodiment, however, a leakage current between the lower electrode 2 and the charge generation layer 42 is reduced, and therefore, it is also possible to prevent a decrease in the light emission efficiency of the organic light-emitting element 900.

In the present exemplary embodiment, the insulating layer 3 includes a groove as the step portion 320 at a position further from the contact portion 230 where the lower electrode 2 and the organic layer 40 are in contact with each other than from the steeply inclined portion 311. Further, a length D of the step portion 320 in the direction perpendicular to the plane parallel to the lower surface of the lower electrode 2 is greater than the length B of the steeply inclined portion 311 in the direction perpendicular to the parallel plane. Consequently, the charge generation layer 42 is thinned more in the step portion 320 than in the steeply inclined portion 311. Thus, it is possible to prevent charges from being generated and transported in a portion located in the direction of an adjacent pixel from the step portion 320.

In this case, the thickness of the first organic layer 41 is also thinned in the step portion 320, but the charge transport layer is thinned in the steeply inclined portion 311, and therefore, a small number of charges reach the step portion 320 from the lower electrode 2. Thus, a leakage current between the lower electrode 2 and the charge generation layer 42 in the step portion 320 is prevented.

Further, in the direction perpendicular to the plane parallel to the lower surface of the lower electrode 2, the length D of the step portion 320 is greater than the distance C from the lower electrode 2 to the charge generation layer 42 in the contact portion 230. Consequently, it is possible to effectively thin the charge generation layer 42 in the step portion 320. Thus, it is possible to prevent charges from being generated and transported in a portion located in the direction of an adjacent pixel from the step portion 320.

In the present exemplary embodiment, the length D of the step portion 320 in the direction perpendicular to the plane parallel to the lower surface of the lower electrode 2 is smaller than a thickness E of the organic layer 40 in the contact portion 230 where the organic layer 40 is in contact with the lower electrode 2. Consequently, the groove as the step portion 320 is buried in the second organic layer 43, and therefore, the second organic layer 43 does not become too thin along the step portion 320. Thus, it is possible to prevent a leakage current between the charge generation layer 42 and the upper electrode 5.

As described above, the insulating layer 3 has the shape according to the present exemplary embodiment, whereby it is possible to reduce a leakage current between organic light-emitting elements 900 while reducing a leakage current between the lower electrode 2 and the charge generation layer 42 or the charge generation layer 42 and the upper electrode 5. Thus, it is possible to prevent an unintended organic light-emitting element 900 from emitting light while preventing a decrease in the light emission efficiency.

It is desirable that in the direction perpendicular to the plane parallel to the lower surface of the lower electrode 2, the depth D of the step portion 320 be greater than a thickness C of the first organic layer 41 (the distance from the lower electrode 2 to the charge generation layer 42) in the contact portion 230. Consequently, it is easy to thin the charge generation layer 42 in the step portion 320, and it is possible to effectively reduce a leakage current between organic light-emitting elements 900.

In the direction perpendicular to the plane parallel to the lower surface of the lower electrode 2, it is also possible to make the length B of the steeply inclined portion 311 greater than the thickness C of the first organic layer 41 (the distance from the lower electrode 2 to the charge generation layer 42) in the contact portion 230. Consequently, it is possible to make the film thickness of not only the lower first organic layer 44 but also the charge generation layer 42 sufficiently small. In this case, however, the film thickness of the first organic layer 41 is too small, and therefore, a leakage current is likely to be generated between the lower electrode 2 and the charge generation layer 42.

Accordingly, in the present exemplary embodiment, the insulating layer 3 includes the steeply inclined portion 311 and further includes the step portion 320 at a position further from the contact portion 230 than from the steeply inclined portion 311.

As described above, the depth D of the step portion 320 in the direction perpendicular to the plane parallel to the lower surface of the lower electrode 2 is greater than the thickness C of the first organic layer 41 in the contact portion 230. In this case, there is a concern about a leakage current between the lower electrode 2 and the charge generation layer 42. In the present exemplary embodiment, however, the steeply inclined portion 311 is closer to the contact portion 230 than to the step portion 320, and the steeply inclined portion 311 reduces charges that move between the organic light-emitting elements 900 by the lower first organic layer 44. Thus, the concern about a leakage current between the lower electrode 2 and the charge generation layer 42 is reduced in the step portion 320.

That is, in the configuration of the present exemplary embodiment, in the steeply inclined portion 311, it is possible to reduce a leakage current between organic light-emitting elements due to the charge transport layer of the lower first organic layer 44, and in the step portion 320, it is also possible to reduce a leakage current between organic light-emitting elements due to the charge generation layer 42. Further, the step portion 320 is disposed further from the contact portion 230 where the lower electrode 2 and the organic layer 40 are in contact with each other than from the steeply inclined portion 311, whereby it is also possible to reduce a leakage current between the lower electrode 2 and the charge generation layer 42.

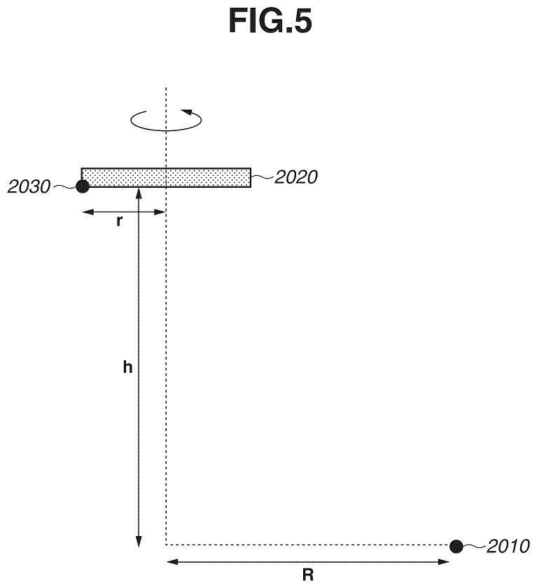

To obtain knowledge regarding the angle of inclination of a desirable inclined portion in the present exemplary embodiment, a film formation simulation by a vapor deposition method was executed. FIG. 5 is a diagram illustrating the placement of members when the vapor deposition simulation was performed. The positions of a vapor deposition source 2010, a substrate 2020, and a semiconductor device 2030 disposed on the substrate 2020 were set as illustrated in FIG. 5 such that R=200 mm, r=95 mm, and h=340 mm.

n representing vapor deposition distribution expressed by the following equation

$$was n = 2. \qquad ( 1 )$$

$$φ = {φ}_{0} {cos}^{n} α \qquad ( 1 )$$

In equation (1), a represents an angle, q represents a vapor flow density at the angle α, and φ₀ represents the vapor flow density when α=0. It was based on the premise that the substrate 2020 rotated at the center of the substrate 2020.

Assuming a case where an inclined portion having an angle of inclination of 0° to 90° was located at the position of the semiconductor device 2030 on the substrate 2020, the layer thickness of a region of an organic layer along the inclined portion at each angle of inclination was calculated when the layer thickness of the organic layer at an angle of inclination of 0° was 76 nm.

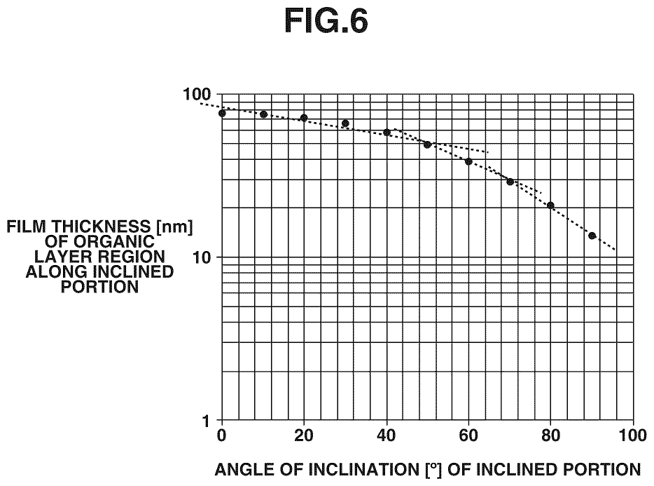

FIG. 6 illustrates the result of the film formation simulation. From this, it is understood that if the angle of inclination is greater than 50°, the layer thickness of the region of the organic layer along the inclined portion is likely to be thin, and if the angle of inclination is less than or equal to 50°, the layer thickness of the region of the organic layer along the inclined portion is likely to be thick. Thus, it is desirable that the angle of inclination of the steeply inclined portion 311 according to the present exemplary embodiment be greater than 50 degrees and less than 180 degrees. Further, from FIG. 6, it is understood that if the angle of inclination is greater than 70°, it is possible to more effectively thin the layer thickness of the region of the organic layer along the inclined portion. Thus, it is more desirable that the angles of inclination of the steeply inclined portion 311 and the step portion 320 according to the present exemplary embodiment be greater than 70 degrees and less than 180 degrees. Consequently, it is possible to thin the lower first organic layer 44 including the charge transport layer, and the charge generation layer 42, and it is possible to prevent a crosstalk current between the organic light-emitting elements 900.

It is desirable that the distance between the light-emitting region 101 and the light-emitting region 201 of the organic light-emitting element 900 be less than or equal to 10 μm. It is more desirable that the distance between the light-emitting region 101 and the light-emitting region 201 be less than or equal to 5 μm. In such high-definition pixel arrangement, a crosstalk current between organic light-emitting elements 900 is likely to be great, and therefore, the effects of the semiconductor device 10 according to the present exemplary embodiment are great.

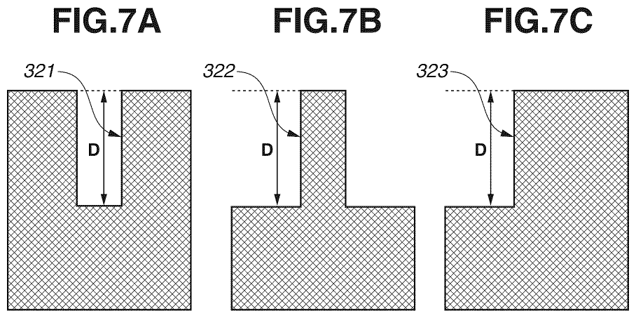

With reference to FIGS. 7A, 7B, and 7C, examples of the shape of the step portion 320 are described. The step portion 320 may be a groove 321 as illustrated in FIG. 7A, or may be a protruding shape 322 as illustrated in FIG. 7B. The step portion 320 may be a step 323 as illustrated in FIG. 7C. The length (the depth D) of the step portion 320 in the direction perpendicular to the plane parallel to the lower surface of the lower electrode 2 corresponds to each of a depth D of the groove 321, a height D of the protruding shape 322, and a height D of the step 323.

It is desirable that each of the groove 321, the protruding shape 322, and the step 323 include a surface portion of the insulating layer 3 inclined such that the angle of inclination θ of the surface portion to the parallel plane parallel to the lower surface of the lower electrode 2 is an angle greater than 50°. Consequently, it is possible to effectively thin the charge generation layer 42. If the angle of inclination θ of each of the groove 321, the protruding shape 322, and the step 323 is greater than 70°, it is possible to more effectively thin the charge generation layer 42, which is desirable. The reason why these angles of inclination of each of the groove 321, the protruding shape 322, and the step 323 are desirable to thin the charge generation layer 42 is clear from the result of the film formation simulation in FIG. 6. If a form is employed in which the step portion 320 includes a surface portion of the insulating layer 3 inversely tapered at 90° or more, it is easy to thin the charge generation layer 42, which is desirable.

It is desirable that the step portion 320 be the groove 321 or the protruding shape 322. This is because each of the groove 321 and the protruding shape 322 includes two steps in a cross-sectional view, and therefore, it is easy to thin the charge generation layer 42.

It is particularly desirable that the step portion 320 be the groove 321. This is because in the groove 321, the material is blocked by the left and right walls of the groove 321 and is less likely to enter into the groove 321 when a film of the charge generation layer 42 is formed, and therefore, it is easy to thin the charge generation layer 42.

As illustrated in FIG. 4, the insulating layer 3 includes a gently inclined portion 330 between the step portion 320 and the steeply inclined portion 311. A length F of the gently inclined portion 330 in the direction perpendicular to the parallel plane is greater than the distance C from the lower electrode 2 to the charge generation layer 42 in the contact portion 230 where the lower electrode 2 and the organic layer 40 are in contact with each other. Consequently, it is possible to make the lower first organic layer 44 and the charge generation layer 42 thinner than those in a place where the surface of the insulating layer 3 is flat, over a long distance without thinning the first organic layer 41 and the second organic layer 43 too much. Thus, it is possible to prevent a leakage current between adjacent lower electrodes 2. The gently inclined portion 330 is a surface portion of the insulating layer 3 inclined such that the angle of inclination θ of the surface portion to the parallel plane parallel to the lower surface of the lower electrode 2 is an angle in the range from 0° to 50°.

It is desirable that the steeply inclined portion 311 be disposed in an end portion of the insulating layer 3. The end portion of the insulating layer 3 doubles as the steeply inclined portion 311, whereby it is possible to save space. This has an advantage in miniaturizing a pixel. The closer to the contact portion 230 where the organic layer 40 and the lower electrode 2 are in contact with each other the steeply inclined portion 311 is, the less likely charges are to be transported onto the insulating layer 3 through the lower first organic layer 44. Thus, it is possible to prevent the emission of light on the insulating layer 3, which is desirable. In the emission of light on the insulating layer 3, unlike the light-emitting regions 101 and 201, optical interference is not appropriately set, and therefore, light of a wavelength different from a desired wavelength is emitted. This causes a decrease in the color purity.

In the cross-sectional view in FIG. 1, in a direction parallel to the lower surface of the lower electrode 2, a distance G from the contact portion 230 where the organic layer 40 and the lower electrode 2 are in contact with each other to the step portion 320 is smaller than a distance H from the step portion 320 to the middle position between the step portion 320 and an adjacent light-emitting element 900. Consequently, the distance from the contact portion 230 to the step portion 320 becomes short, and therefore, the range where the emission of light can occur on the insulating layer 3 becomes narrow. Thus, it is possible to prevent a decrease in the color purity, which is desirable. The middle position between the step portion 320 and the adjacent pixel means the midpoint between the closest ends of the lower electrodes 2 of adjacent organic light-emitting elements 900 in the direction parallel to the lower surfaces of the lower electrodes 2.

It is desirable that both the steeply inclined portion 311 and the step portion 320 overlap the lower electrode 2 in the planar view. Consequently, an electric field generated by the potential difference between the lower electrode 2 and the upper electrode 5 is applied to the organic layer 40 thinned by the step portion 320, and therefore, the recombination of charges is promoted. Thus, it is possible to prevent a leakage current between adjacent lower electrodes 2.

As illustrated in the cross-sectional view in FIG. 1, it is desirable that the apexes of the contact portion 230 and the microlens 222 overlap each other in the planar view. The angle of inclination to the parallel plane parallel to the lower surface of the lower electrode 2 at a position J on the surface of the microlens 222 immediately over an end portion of the contact portion 230 is an angle of inclination Φj. The angle of inclination to the parallel plane at a position K on the surface of the microlens 222 immediately over the closest position of the step portion 320 to the contact portion 230 is an angle of inclination Φk. At this time, it is desirable that the angle of inclination Φk be greater than the angle of inclination Φj. The reason is described below.

If waveguide light in a horizontal direction is scattered in the steeply inclined portion 311 or the step portion 320, optical interference is not appropriately set, and light of a wavelength different from a desired wavelength is extracted in the up direction. Then, the color purity can deteriorate. However, due to the presence of the inclination of the surface of the microlens 222, light is refracted and is less likely to be extracted in the up direction. In this case, the greater the angle of inclination is, the greater the effect is. In the present exemplary embodiment, since the depth D of the step portion 320 is greater than the height B of the steeply inclined portion 311, the amount of scattered light in the step portion 320 is great. Accordingly, the angle of inclination Φk is made greater than the angle of inclination Φj, whereby it is possible to further prevent the scattered light from being extracted in the up direction.

As illustrated in FIG. 4, it is desirable that the lower end of the groove as the step portion 320 be located at a position higher than the upper end of the steeply inclined portion 311. Consequently, it is possible to prevent color mixture and improve the color purity. The reason is described below.

Light emitted from a light-emitting layer enters the insulating layer 3 through the steeply inclined portion 311 as an entrance and guides a wave in a horizontal direction through the insulating layer 3. The step portion 320 is present in the insulating layer 3, whereby the path of the waveguide light is restricted. Thus, the waveguide light is less likely to reach an adjacent light-emitting element, and light extracted through the color filter of the adjacent pixel decreases. The step portion 320 is present on an upper side, whereby it is possible to block light in an upper portion likely to be involved in color mixture. Thus, the effect of preventing color mixture is great.

A method for manufacturing the semiconductor device 10 according to the first exemplary embodiment can use steps similar to those in Japanese Patent Application Laid-Open No. 2021-072282.

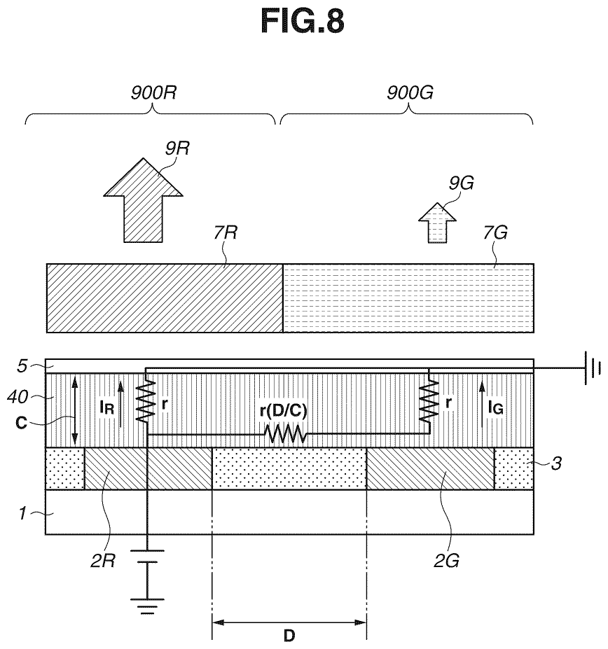

In a light-emitting device in FIG. 8, the resistance per unit area of the organic layer 40 in the direction parallel to the lower surface of the lower electrode 2 is r (D/C). Based on this, in a case where a current flowing through an organic light-emitting element 900R is IR and a current flowing through an organic light-emitting element 900G is IG, the following relationship holds.

$$IG / IR = 1 / ( 1 + D / C ) \qquad ( 2 )$$

From the above equation (2), it is understood that the current flowing through the organic light-emitting element 900R and the current flowing through the organic light-emitting element 900G have a proportional relationship with the thickness C of the organic layer 40 and the distance D as coefficients. That is, even if only the red organic light-emitting element 900R is caused to emit light, a current also flows through the green organic light-emitting element 900G, and the green organic light-emitting element 900G also emits light. This depends on D/C.

In a case where the light emission spectrum of only the red organic light-emitting element 900R is SR and the light emission spectrum of only the green organic light-emitting element 900G is SG when the red organic light-emitting element 900R and the red organic light-emitting element 900R are caused to emit light with the same amount of current, a light emission spectrum SR+G with a leakage current between the lower electrodes 2 reflected is expressed by the following equation (3).

$$SR + G = SR + SG ( IG / IR ) \qquad ( 3 )$$

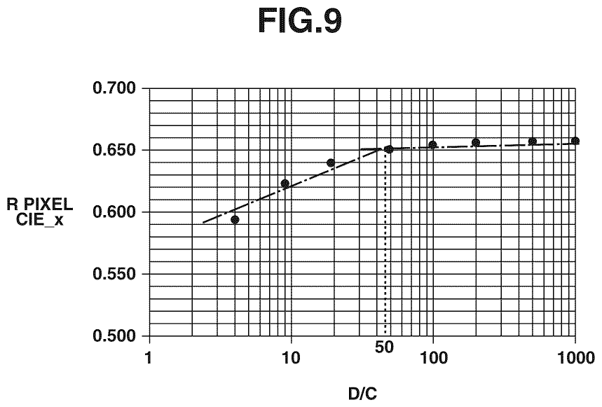

FIG. 9 illustrates a graph which is obtained by calculating the chromaticity coordinates of the light emission spectrum SR+G in the International Commission on Illumination (CIE) xy space and where the vertical axis represents the x-value and the horizontal axis represents the ratio D/C. In FIG. 9, that the x-coordinate changes means that even though red light is intended to be emitted, green light is also emitted. That is, in FIG. 9, that the x-coordinate is low means that a leakage current to an adjacent pixel is generated. If the ratio D/C is greater than or equal to 50, the x-value hardly changes. That is, it is understood that even in a case where the inclined portions of the insulating layer 3 are not present and a leakage current between the lower electrodes 2 is likely to be generated, if the ratio D/C is greater than or equal to 50, the leakage current between the lower electrodes 2 may not be an issue.

It is understood that, on the other hand, if the ratio D/C is less than 50, the x-value greatly decreases, a decrease in the color purity of red is remarkable, and a leakage current between the lower electrodes 2 influences the color purity. That is, if the ratio D/C is less than 50, the density of arrangement of organic light-emitting elements is high, and therefore, the influence of the leakage current between the lower electrodes 2 on the semiconductor device 10 is remarkable. Thus, if the ratio D/C is less than 50, the effect of preventing a leakage current between lower electrodes 2 is particularly high.

Next, a structure with the optical interference of each organic light-emitting element 900 reflected is described. The optical distance between the upper electrode 5 and the lower electrode 2 of the light-emitting element 900 according to the present exemplary embodiment may have a mutually-strengthening-interference structure. The mutually strengthening interference structure can also be said to be a resonance structure. In the organic light-emitting element 900, the plurality of layers included in the organic layer 40 is formed to satisfy a mutually strengthening optical interference condition, whereby it is possible to strengthen extracted light from the semiconductor device 10 by optical interference.

Under an optical condition for strengthening extracted light in a front surface direction, light is emitted in the front surface direction with higher efficiency. It is known that the half width of the light emission spectrum of light strengthened by optical interference is smaller than the light emission spectrum before the interference. That is, it is possible to increase the color purity.

In a case where the semiconductor device 10 is designed for light of a wavelength λ, a distance do from the light-emitting position of a light-emitting layer to a reflection surface of a light reflection material is adjusted to d0=iλ/4n0 (i=1, 3, 5, . . . ), whereby it is possible to achieve mutually strengthening interference.

As a result, there are many components in the front surface direction in the distribution of emission of the light of the wavelength λ, and the front surface luminance improves.

n0 is the refractive index at the wavelength λ of a layer from the light-emitting position to the reflection surface.

An optical distance Lr from the lower surface of the light-emitting layer to a reflection surface of a light reflection electrode is expressed by the following equation (4), where the sum of the phase shift amounts when the light of the wavelength A is reflected on the reflection surface is or [rad]. An optical distance L is the sum of the products of a refractive index nj of each layer of the organic layer 40 and a thickness dj of the layer. That is, L can be represented as Σnj×dj, and can also be represented as n0×d0. φ is a negative value.

$$Lr = ( 2 m - ( φ r / π ) ) \times ( λ / 4 ) \qquad ( 4 )$$

In the above equation (4), m is an integer greater than or equal to 0. If φ=−π and m=0, L=λ/4. If m=1, L=3λ/4. Hereinafter, the condition that m=0 in the above equation (4) is referred to as a “λ/4 interference condition”, and the condition that m=1 in the above equation (4) is referred to as a “32/4 interference condition”.

An optical distance Ls from the light-emitting position to a reflection surface of a light extraction electrode is expressed by the following equation (5), where the sum of the phase shifts when the light of the wavelength λ is reflected on the reflection surface is φs [rad]. In the following equation (5), m′ is an integer greater than or equal to 0.

$$Ls = ( 2 {m}^{′} - ( φ s / π ) ) \times ( λ / 4 ) = - ( φ s / π ) \times ( λ / 4 ) \qquad ( 5 )$$

Thus, an all-layers interference L is as illustrated in the following equation (6).

$$L = ( Lr + Ls ) = ( 2 m - ( Φ / \prod ) ) \times ( Λ / 4 ) \qquad ( 6 )$$

φ is the sum (φr+φs) of the phase shifts when the light of the wavelength λ is reflected on the light reflection electrode and the light extraction electrode.

At this time, an actual organic light-emitting element does not need to strictly match the above equation (6) in view of viewing angle characteristics having a trade-off relationship with the extraction efficiency of the front surface. Specifically, L may have an error in the range from a value satisfying equation (6) to values of ±λ/8. An acceptable value that allows the value of L to be away from the interference condition may be 50 nm or more and 75 nm or less.

Thus, it is desirable that the organic light-emitting element 900 according to the present exemplary embodiment satisfy the following equation (7). It is further desirable that L be in the range from a value satisfying equation (6) to values of ±λ/16, and it is desirable that the organic light-emitting element 900 satisfy the following equation (7′).

$$( λ / 8 ) \times ( 4 m - ( 2 φ / π ) - 1 ) < L < ( λ / 8 ) \times ( 4 m - ( 2 φ / π ) + 1 ) \qquad ( 7 )$$

$$( λ / 16 ) \times ( 8 m - ( 4 φ / π ) - 1 ) < L < ( λ / 16 ) \times ( 8 m - ( 4 φ / π ) + 1 ) \qquad ( {7}^{′} )$$

It is desirable that the organic light-emitting element 900 satisfy m=0 and m′=0, i.e., the λ/4 optical interference condition, in equations (7) and (7′). In this case, equations (7) and (7′) are expressed as in equations (8) and (8′).

$$( λ / 8 ) \times ( - ( 2 φ / π ) - 1 ) < L < ( λ / 8 ) \times ( - ( 2 φ / π ) + 1 ) \qquad ( 8 )$$

$$( λ / 16 ) \times ( - ( 4 φ / π ) - 1 ) < L < ( λ / 16 ) \times ( - ( 4 φ / π ) + 1 ) \qquad ( {8}^{′} )$$

If m=0 and m′=0 in equations (7) and (7′), the film thickness of the organic layer 40 is thinnest in the mutually strengthening interference structure. Consequently, the driving voltage of the organic light-emitting element 900 is low, and light can be emitted with higher luminance in the upper limit range of a power supply voltage. In a case where the organic layer 40 is thin, a leakage current between the upper electrode 5 and the lower electrode 2 is likely to be generated. Thus, the organic layer 40 cannot be easily thinned using the inclination of the insulating layer 3. Thus, the requirements described in the present exemplary embodiment are satisfied, whereby it is possible to prevent a leakage current between the upper electrode 5 and the lower electrode 2 while further sufficiently preventing a leakage current between lower electrodes 2.

The light emission wavelength λ may be a light emission wavelength at the maximum peak in the light emission spectrum of the light emitted from the light-emitting layer. Generally, regarding the maximum peak in the emission of light from an organic compound, the minimum peak in the light emission spectrum is the maximum light emission. Thus, the light emission wavelength λ may be a wavelength at the minimum peak.

It is desirable that the thickness of a portion of the organic layer 40 in contact with the lower electrode 2 in the direction perpendicular to the lower surface of the lower electrode 2 be less than 200 nm. Consequently, it is easy to make the driving voltage of the semiconductor device 10 low. The effect of reducing a leakage current between the upper electrode 5 and the lower electrode 2 while reducing a leakage current between lower electrodes 2 according to the present exemplary embodiment is great.

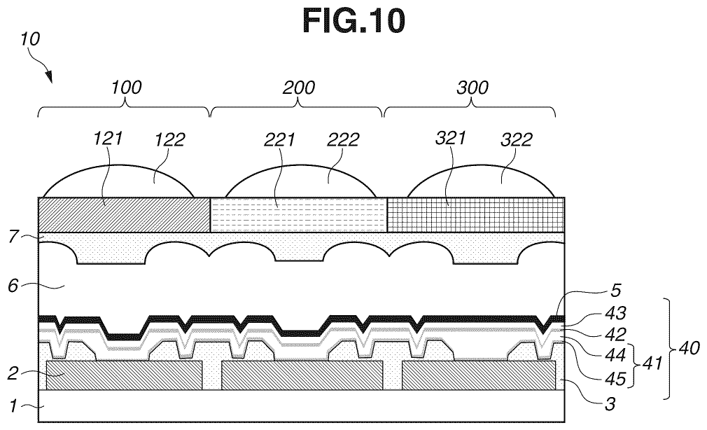

FIG. 10 illustrates an example of a semiconductor device 10 according to a second exemplary embodiment. In the present exemplary embodiment, the same component as or a component similar to that in the first exemplary embodiment is designated by the same reference number, and is not redundantly described.

The semiconductor device 10 in FIG. 10 has a configuration similar to that according to the first exemplary embodiment except that the lower electrode 2 is disposed in contact with the element substrate 50, the semiconductor device 10 does not include the optical interference layer 30 and the reflection portion 105, and the configuration changes accordingly. It is desirable that as the change in the configuration according to the absence of the reflection portion 105, for example, the lower electrode 2 have light reflectivity. The specific configuration of the insulating layer 3 is similar to that illustrated in FIG. 4.

Also with this configuration, the insulating layer 3 includes the steeply inclined portion 311 and the step portion 320 illustrated in the first exemplary embodiment, whereby it is possible to obtain the following effects. Specifically, it is possible to both reduce a leakage current between adjacent organic light-emitting elements and reduce a leakage current between the lower electrode 2 and the charge generation layer 42 or the charge generation layer 42 and the upper electrode 5.

Specifically, in a cross section in FIG. 10, the length B of the steeply inclined portion 311 on the parallel plane parallel to the lower surface of the lower electrode 2 is greater than the distance A from the lower electrode 2 (the first electrode) to the first light-emitting layer 45 in the contact portion 230. Consequently, the lower first organic layer 44 including the charge transport layer is thinned along the steeply inclined portion 311. Thus, it is possible to prevent charges from being transported to a portion located in the direction of the step portion 320 from the steeply inclined portion 311 in FIG. 4. Thus, it is possible to prevent a leakage current between adjacent organic light-emitting elements.

The length D of the step portion 320 in the direction perpendicular to the plane parallel to the lower surface of the lower electrode 2 is greater than the length B of the steeply inclined portion 311 in the direction perpendicular to the parallel plane. Consequently, the charge generation layer 42 is thinned more in the step portion 320 than in the steeply inclined portion 311. Thus, it is possible to prevent charges from being generated and transported in a portion located in the direction of an adjacent pixel from the step portion 320.

In the present exemplary embodiment, the length D of the step portion 320 in the direction perpendicular to the plane parallel to the lower surface of the lower electrode 2 is smaller than the thickness E of the organic layer 40 in the contact portion 230. Consequently, the groove as the step portion 320 is buried in the second organic layer 43, and therefore, the second organic layer 43 does not become too thin along the step portion 320. Thus, it is possible to prevent a leakage current between the charge generation layer 42 and the upper electrode 5.

Further, in the direction perpendicular to the plane parallel to the lower surface of the lower electrode 2, the length B of the steeply inclined portion 311 is smaller than the distance C from the lower electrode 2 to the charge generation layer 42 in the contact portion 230 where the organic layer 40 is in contact with the lower electrode 2. Consequently, the steeply inclined portion 311 is buried in the first organic layer 41, and therefore, the first organic layer 41 does not become too thin along the steeply inclined portion 311. Thus, it is possible to prevent a current leakage between the lower electrode 2 and the charge generation layer 42.

In the direction perpendicular to the plane parallel to the lower surface of the lower electrode 2, the length D of the step portion 320 is greater than the distance C from the lower electrode 2 to the charge generation layer 42 in the contact portion 230. Consequently, it is possible to effectively thin the charge generation layer 42 in the step portion 320. Thus, it is possible to prevent charges from being generated and transported in a portion located in the direction of an adjacent pixel from the step portion 320.

A semiconductor device according to a third exemplary embodiment can be used as a component member of a display apparatus or an illumination apparatus. Alternatively, the semiconductor device can be applied to an exposure light source of an electrophotographic image forming apparatus, a backlight of a liquid crystal display apparatus, or a light-emitting device including a color filter in a white light source.

The display apparatus may be an image information processing apparatus that includes an image input unit to which image information from an area charge-coupled device (CCD), a linear CCD, or a memory card is input, includes an information processing unit that processes the input information, and displays an input image on a display unit.

A display unit included in an imaging apparatus or an inkjet printer may have a touch panel function. A method for driving the touch panel function may be an infrared method, a capacitive method, a resistive method, or an electromagnetic induction method, and is not particularly limited. The display apparatus may be used in a display unit of a multifunction printer.

Next, with reference to the drawings, a display apparatus according to the present exemplary embodiment is described.

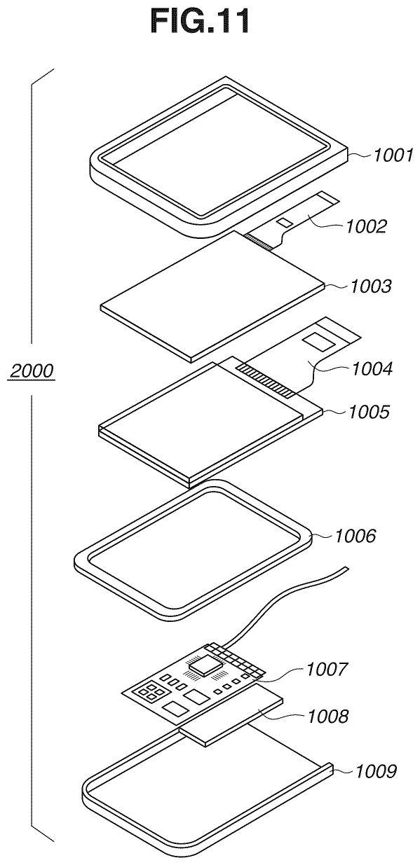

FIG. 11 is a schematic view illustrating an example of the display apparatus according to the present exemplary embodiment. A display apparatus 2000 may include a touch panel 1003, a display panel 1005, a frame 1006, a circuit substrate 1007, and a battery 1008 between an upper cover 1001 and a lower cover 1009. The touch panel 1003 and the display panel 1005 are connected to flexible printed circuits (FPCs) 1002 and 1004, respectively. On the circuit substrate 1007, a transistor is printed. The battery 1008 may not be provided unless the display apparatus 1000 is a mobile device, or may be provided at another position even if the display apparatus 1000 is a mobile device.

The display apparatus according to the present exemplary embodiment may include color filters having red, green, and blue colors. In the color filters, the red, green, and blue colors may be arranged in the delta arrangement.

The display apparatus according to the present exemplary embodiment may be used in a display unit of a mobile terminal. At this time, the display apparatus may have both a display function and an operation function. Examples of the mobile terminal include a mobile phone such as a smartphone, a tablet, and a head-mounted display.

The display apparatus according to the present exemplary embodiment may be used in a display unit of an imaging apparatus including an optical unit that includes a plurality of lenses, and an imaging element that receives light passing through the optical unit. The imaging apparatus may include a display unit that displays information acquired by the imaging element. The display unit may be a display unit exposed to outside the imaging apparatus, or may be a display unit placed in a viewfinder. The imaging apparatus may be a digital camera or a digital video camera.

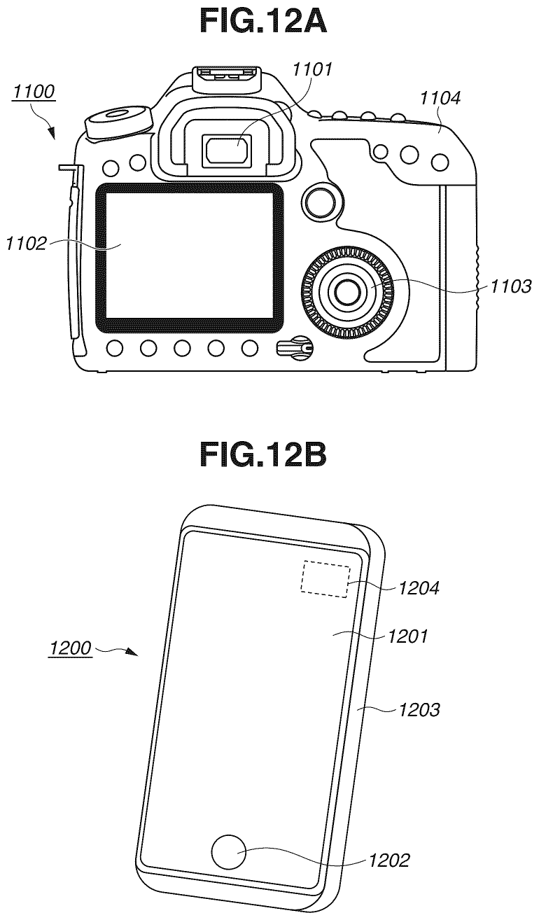

FIG. 12A is a schematic view illustrating an example of an imaging apparatus according to the present exemplary embodiment. An imaging apparatus 1100 may include a viewfinder 1101, a back surface display 1102, an operation unit 1103, and a housing 1104. The viewfinder 1101 may include the display apparatus according to the present exemplary embodiment. In this case, the display apparatus may display not only a captured image, but also environment information and an image capturing instruction. The environment information may include the intensity of external light, the direction of external light, the moving speed of an object, and the possibility that an object is blocked by a blocking object.

Since a timing suitable for capturing an image lasts for a short time, the information might as well be displayed as soon as possible. Thus, it is desirable to use a display apparatus using an organic light-emitting element according to the present disclosure. This is because the response speed of the organic light-emitting element is fast. The display apparatus using the organic light-emitting element can be used more suitably than these apparatuses and a liquid crystal display apparatus, which require a fast display speed.

The imaging apparatus 1100 includes an optical unit (not illustrated). The optical unit includes a plurality of lenses and forms an image on an imaging element accommodated in the housing 1104. The focus can be adjusted by adjusting the relative positions of the plurality of lenses. This operation can also be performed automatically. The imaging apparatus 1100 may also be referred to as a “photoelectric conversion apparatus”. The photoelectric conversion apparatus can include a method for detecting the difference from the previous image without sequentially capturing images or a method for clipping an image from an always recorded image as an imaging method.

FIG. 12B is a schematic view illustrating an example of an electronic device according to the present exemplary embodiment. An electronic device 1200 includes a display unit 1201, an operation unit 1202, and a housing 1203. The housing 1203 may include a circuit, a printed substrate including the circuit, a battery, and a communication unit 1204. The operation unit 1202 may be a button, or may be a response unit using a touch panel method. The operation unit 1202 may be a biometric unit that recognizes a fingerprint and releases a lock. The electronic device 1200 including the communication unit 1204 can also be said to be a communication device. The electronic device 1200 may further have a camera function by including a lens and an imaging element. An image captured by the camera function is displayed on the display unit 1201. Examples of the electronic device 1200 include a smartphone and a laptop personal computer.

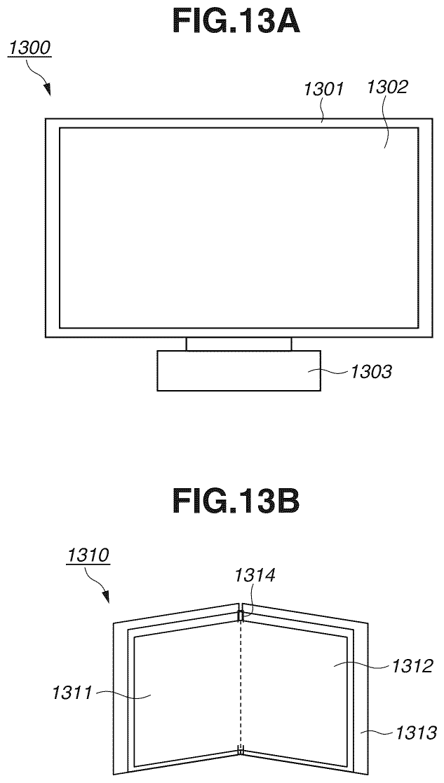

FIGS. 13A and 13B are schematic views illustrating examples of a display apparatus according to the present exemplary embodiment. FIG. 13A illustrates a display apparatus such as a television monitor or a personal computer (PC) monitor. A display apparatus 1300 includes a frame 1301 and a display unit 1302. A light-emitting device according to the present exemplary embodiment may be used in the display unit 1302.

The display apparatus 1300 includes a base 1303 that supports the frame 1301 and the display unit 1302. The base 1303 is not limited to the form in FIG. 13A. The lower side of the frame 1301 may double as a base.

The frame 1301 and the display unit 1302 may be curved. The radius of curvature of the curve may be 5000 mm or more and 6000 mm or less.

FIG. 13B is a schematic view illustrating another example of the display apparatus according to the present exemplary embodiment. A display apparatus 1310 in FIG. 13B is configured to be folded and is a so-called foldable display apparatus. The display apparatus 1310 includes a first display unit 1311, a second display unit 1312, a housing 1313, and a folding point 1314. The first display unit 1311 and the second display unit 1312 may include the light-emitting device according to the present exemplary embodiment. The first display unit 1311 and the second display unit 1312 may be a single display apparatus without a joint. The first display unit 1311 and the second display unit 1312 can be divided at the folding point 1314. The first display unit 1311 and the second display unit 1312 may display images different from each other, or may display a single image.

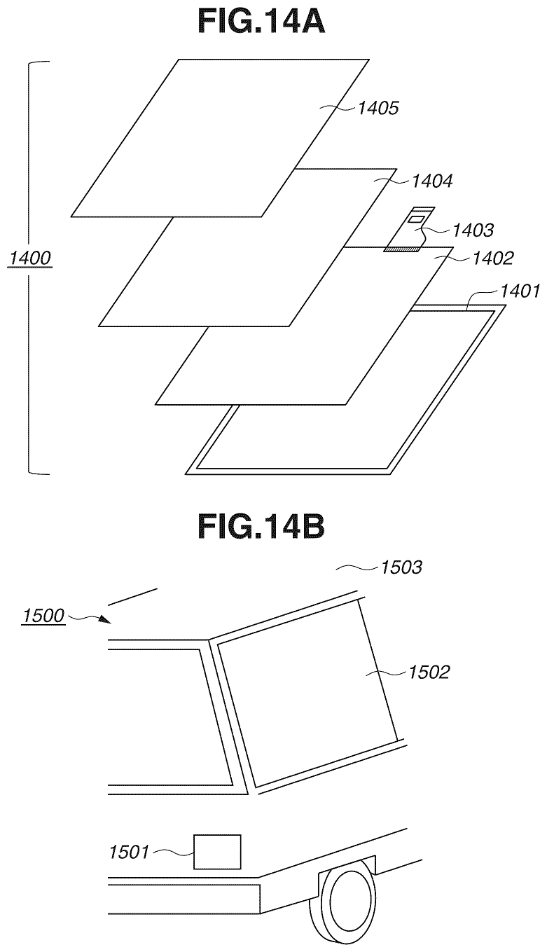

FIG. 14A is a schematic view illustrating an example of an illumination apparatus according to the present exemplary embodiment. An illumination apparatus 1400 may include a housing 1401, a light source 1402, a circuit substrate 1403, an optical film 1404, and a light diffusion unit 1405. The light source 1402 may include an organic light-emitting element according to the present exemplary embodiment. The optical film 1404 may be a filter for improving the color rendering properties of the light source 1402. The light diffusion unit 1405 can effectively diffuse light of the light source 1402 by lighting up and deliver the light to a wide range. The optical film 1404 and the light diffusion unit 1405 may be provided on the light exit side of the illumination. A cover may be provided in an outermost portion of the illumination apparatus 1400, where necessary.

For example, the illumination apparatus 1400 is an apparatus that illuminates the inside of a room. The illumination apparatus 1400 may emit light of white, daylight white, or any of colors from blue to red. The illumination apparatus 1400 may include a light modulation circuit that modulates the light.

The illumination apparatus 1400 may include the organic light-emitting element according to the present disclosure and a power supply circuit connected to the organic light-emitting element. The power supply circuit is a circuit that converts an alternating-current voltage into a direct-current voltage. The color temperature of white is 4200 K, and the color temperature of daylight white is 5000 K. The illumination apparatus 1400 may include a color filter.

The illumination apparatus according to the present exemplary embodiment may include a heat release unit. The heat release unit releases heat in the apparatus to outside the apparatus. Examples of the heat release unit include a metal having high specific heat and liquid silicon.

FIG. 14B is a schematic view illustrating an automobile as an example of a movable object according to the present exemplary embodiment. The automobile includes a taillight as an example of a lamp fitting. An automobile 1500 may include a taillight 1501 and have a form in which the automobile 1500 lights up the taillight 1501 when a brake operation is performed.

The taillight 1501 may include the organic light-emitting element according to the present exemplary embodiment. The taillight 1501 may include a protection member that protects an organic EL element. The material of the protection member does not matter so long as the material has somewhat high strength and is transparent. It is, however, desirable that the protection member be composed of polycarbonate. The polycarbonate may be mixed with a furandicarboxylic acid derivative or an acrylonitrile derivative.

The automobile 1500 may include a vehicle body 1503 and a window 1502 attached to the vehicle body 1503. The window 1502 may be a transparent display if the window 1502 is not a window for checking ahead of or behind the automobile 1500. The transparent display may include the organic light-emitting element according to the present exemplary embodiment. In this case, the constituent material of an electrode included in the organic light-emitting element is composed of a transparent member.

The movable object according to the present exemplary embodiment may be a vessel, an aircraft, or a drone. The movable object may include a body and a lamp fitting provided in the body. The lamp fitting may emit light to notify a user of the position of the body. The lamp fitting includes the organic light-emitting element according to the present exemplary embodiment.

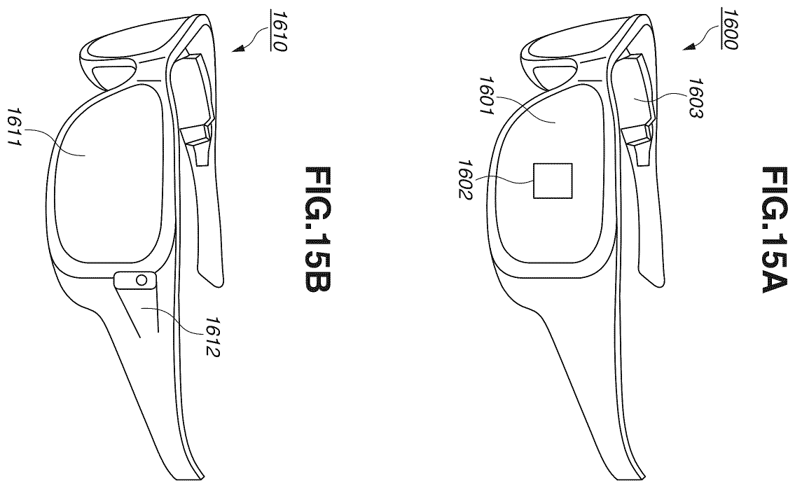

With reference to FIGS. 15A and 15B, application examples of the display apparatus according to each of the above exemplary embodiments are described. The display apparatus can be applied to a system that can be worn as a wearable device such as smartglasses, a head-mounted display (HMD), or smart contact lenses. An imaging display apparatus used in such application examples includes an imaging apparatus capable of photoelectrically converting visible light and a display apparatus capable of emitting visible light.

FIG. 15A illustrates eyeglasses 1600 (smartglasses) according to an application example. On the front surface of a lens 1601 of the eyeglasses 1600, an imaging apparatus 1602 such as a complementary metal-oxide-semiconductor (CMOS) sensor or a single-photon avalanche diode (SPAD) is provided. On the back surface of the lens 1601, the display apparatus according to each of the above exemplary embodiments is provided.

The eyeglasses 1600 further include a control apparatus 1603. The control apparatus 1603 functions as a power supply that supplies power to the imaging apparatus 1602 and the display apparatus according to each of the exemplary embodiments. The control apparatus 1603 controls the operations of the imaging apparatus 1602 and the display apparatus. In the lens 1601, an optical system for collecting light on the imaging apparatus 1602 is formed.

FIG. 15B illustrates eyeglasses 1610 (smartglasses) according to an application example. The eyeglasses 1610 include a control apparatus 1612. On the control apparatus 1612, an imaging apparatus equivalent to the imaging apparatus 1602 and the display apparatus are mounted. In a lens 1611, an optical system for projecting light emitted from the display apparatus in the control apparatus 1612 is formed. An image is projected onto the lens 1611. The control apparatus 1612 functions as a power supply that supplies power to the imaging apparatus and the display apparatus, and also controls the operations of the imaging apparatus and the display apparatus. The control apparatus 1612 may include a line-of-sight detection unit that detects the line of sight of a wearer (a user). The line of sight may be detected using infrared light. An infrared light-emitting unit emits infrared light to the eyeball of the user gazing at the display image. An imaging unit including a light-receiving element detects reflected light of the emitted infrared light from the eyeball, thereby obtaining a captured image of the eyeball. The control apparatus 1612 includes a reduction unit that reduces light from the infrared light-emitting unit to a display unit in a planar view, thereby reducing a decrease in the grade of the image.

The line of sight of the user to the display image is detected from the captured image of the eyeball obtained by capturing the infrared light. Any known technique can be applied to the line-of-sight detection using the captured image of the eyeball. As an example, a line-of-sight detection method based on a Purkinje image formed by the reflection of emitted light in the cornea can be used.

More specifically, a line-of-sight detection process based on a pupil-corneal reflection method is performed. Using the pupil-corneal reflection method, a line-of-sight vector indicating the direction (the rotation angle) of the eyeball is calculated based on an image of the pupil and a Purkinje image included in the captured image of the eyeball, thereby detecting the line of sight of the user.

A display apparatus according to an exemplary embodiment of the present disclosure may include an imaging apparatus including a light-receiving element and control a display image on the display apparatus based on line-of-sight information regarding a user from the imaging apparatus.

Specifically, based on the line-of-sight information, the display apparatus determines a first display region gazed at by the user and a second display region other than the first display region. The first and second display regions may be determined by a control apparatus of the display apparatus, or the display apparatus may receive the first and second display regions determined by an external control apparatus. In a display region of the display apparatus, the display resolution of the first display region may be controlled to be higher than the display resolution of the second display region. That is, the resolution of the second display region may be lower than the first display region.

The display region includes the first display region and the second display region different from the first display region, and a region having high priority is determined between the first and second display regions based on the line-of-sight information. The first and second display regions may be determined by the control apparatus of the display apparatus, or the display apparatus may receive the first and second display regions determined by an external control apparatus. The resolution of the region having high priority may be controlled to be higher than the resolution of a region other than the region having high priority. That is, the resolution of a region having relatively low priority may be set to be low.

The first display region and the region having high priority may be determined using artificial intelligence (AI). The AI may be a model configured to, using as supervised data an image of an eyeball and a direction actually viewed by the eyeball in the image, estimate the angle of the line of sight and the distance to an object in the line of sight based on an image of an eyeball. An AI program may be included in the display apparatus, or may be included in the imaging apparatus, or may be included in an external apparatus. In a case where the AI program is included in the external apparatus, the AI program is transmitted from the external apparatus to the display apparatus through communication.

In a case where display control is performed based on line-of-sight detection, the display apparatus can be suitably applied to smartglasses further including an imaging apparatus that captures outside. The smartglasses can display information regarding the captured outside in real time.

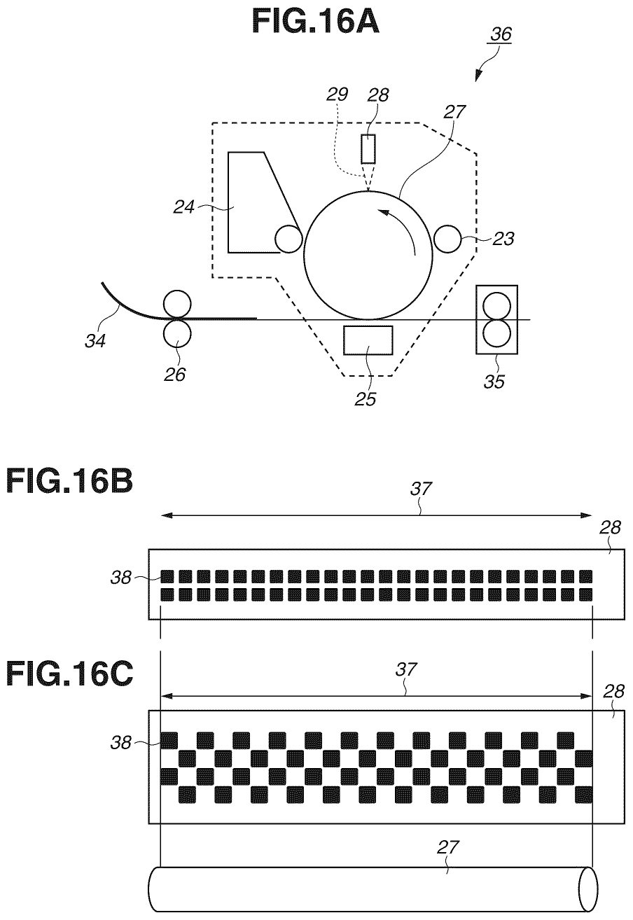

FIGS. 16A, 16B, and 16C illustrate an image forming apparatus according to an exemplary embodiment of the present disclosure. FIG. 16A is a schematic view illustrating an image forming apparatus 40 according to the exemplary embodiment of the present disclosure. The image forming apparatus 36 includes a photosensitive member 27, an exposure light source 28, a development unit 24, a charging unit 23, a transfer device 25, conveyance rollers 26, and a fixing device 35.

The exposure light source 28 emits light 29, and an electrostatic latent image is formed on the surface of the photosensitive member 27. The exposure light source 28 includes the organic light-emitting element according to the present disclosure. The development unit 24 has toner. The charging unit 23 charges the photosensitive member 27. The transfer device 25 transfers a developed image to a recording medium 34. The conveyance rollers 26 convey the recording medium 34. For example, the recording medium 34 is paper. The fixing device 35 fixes the image formed on the recording medium 34.

FIGS. 16B and 16C are schematic views illustrating the state where a plurality of light-emitting units 38 is placed on a long substrate in the exposure light source 28. An arrow 37 indicates a direction parallel to the shaft of the photosensitive member 27 and indicates the column direction in which organic light-emitting elements are arranged. This column direction is the same as the direction of an axis about which the photosensitive member 27 rotates. This direction can also be referred to as “the long axis direction of the photosensitive member 27”.

FIG. 16B illustrates a form in which the light-emitting units 38 are placed along the long axis direction of the photosensitive member 27. FIG. 16C illustrates a form different from that in FIG. 16B, and is a form in which light-emitting units 38 are alternately placed in the column direction in each of a first column and a second column. The first and second columns are placed at different positions in the row direction.

In the first column, a plurality of light-emitting units 38 is placed at intervals. The second column has light-emitting units 38 at positions corresponding to the intervals between the light-emitting units 38 in the first column. That is, a plurality of light-emitting units 38 is placed at intervals also in the row direction.

For example, the arrangement in FIG. 16C can be restated as the state where the light-emitting units 38 are arranged in a grid pattern, the state where the light-emitting units 38 are arranged in a houndstooth pattern, or a checkerboard pattern.

As described above, through the use of an apparatus using the organic light-emitting element according to the present exemplary embodiment, it is possible to perform stable display also in long-term display with excellent image quality.

According to the present disclosure, it is possible to provide a semiconductor device that prevents a leakage current between light-emitting elements and a leakage current between an upper electrode and a lower electrode.

While the present disclosure has been described with reference to exemplary embodiments, it is to be understood that the disclosure is not limited to the disclosed exemplary embodiments. The scope of the following claims is to be accorded the broadest interpretation so as to encompass all such modifications and equivalent structures and functions.

This application claims the benefit of Japanese Patent Application No. 2023-161737, filed Sep. 25, 2023, which is hereby incorporated by reference herein in its entirety.

What is claimed is:

1. A semiconductor device comprising:
a first electrode disposed over an element substrate;
an insulating layer that covers an end of the first electrode;
an organic layer disposed over the first electrode and the insulating layer; and
a second electrode disposed over the organic layer,
wherein the organic layer includes a first light-emitting layer, a charge transport layer disposed between the first electrode and the first light-emitting layer, and a charge generation layer disposed between the first light-emitting layer and the second electrode,
wherein the insulating layer includes a step portion and a steeply inclined portion,
wherein the steeply inclined portion is inclined with an angle between the steeply inclined portion and a parallel plane parallel to a lower surface of the first electrode being greater than 50°,
wherein a distance from the step portion to a contact portion where the first electrode and the organic layer are in contact with each other is greater than a distance from the step portion to the steeply inclined portion, and
wherein, in a cross section through the element substrate, the first electrode, and the insulating layer, in a direction perpendicular to the parallel plane, a length of the steeply inclined portion is greater than a distance from the first electrode to the first light-emitting layer in the contact portion, and in the direction perpendicular to the parallel plane, a length of the step portion is greater than the length of the steeply inclined portion and smaller than a thickness of the organic layer in the contact portion.

2. The semiconductor device according to claim 1, wherein, in the direction perpendicular to the parallel plane in the cross section, the length of the steeply inclined portion is smaller than a distance from the first electrode to the charge generation layer in the contact portion.

3. The semiconductor device according to claim 1, wherein in the direction perpendicular to the parallel plane in the cross section, the length of the step portion is greater than a distance from the first electrode to the charge generation layer in the contact portion.

4. The semiconductor device according to claim 1, wherein the step portion is a groove.

5. The semiconductor device according to claim 1,
wherein the insulating layer includes a gently inclined portion between the step portion and the steeply inclined portion, and
wherein in the direction perpendicular to the parallel plane in the cross section, a length of the gently inclined portion is greater than a distance from the first electrode to the charge generation layer in the contact portion.

6. The semiconductor device according to claim 1, wherein the steeply inclined portion is located over the first electrode and in an end portion of the insulating layer.

7. The semiconductor device according to claim 1, wherein, in a planar view with respect to the parallel plane, the step portion overlaps the first electrode.

8. The semiconductor device according to claim 1, wherein, in the cross section, a lower end of the step portion is at a position where a distance from the lower end of the step portion to the lower surface of the first electrode is greater than a distance from the lower end of the step portion to an upper end of the steeply inclined portion.

9. The semiconductor device according to claim 1, further comprising a reflection layer between the element substrate and the first electrode.

10. The semiconductor device according to claim 1, further comprising:
a reflection layer between the element substrate and the first electrode; and
a conductive layer disposed over the reflection layer,
wherein the conductive layer has an opening, and
wherein, in a planar view with respect to the lower surface of the first electrode, the contact portion is included in the opening.

11. The semiconductor device according to claim 10, wherein, in the cross section, the steeply inclined portion is disposed over the reflection layer in the opening of the conductive layer, and the step portion is disposed over the conductive layer.

12. The semiconductor device according to claim 1, further comprising a third electrode disposed over the element substrate and adjacent to the first electrode with the insulating layer interposed between the first electrode and the third electrode,
wherein the insulating layer covers an end of the third electrode,
wherein the second electrode is disposed over the third electrode with the organic layer interposed between the second electrode and the third electrode, and
wherein, in a direction parallel to the lower surface of the first electrode in the cross section, a distance from the contact portion to the step portion is smaller than a distance from the step portion to a middle position between the first and third electrodes.

13. The semiconductor device according to claim 1, further comprising a third electrode disposed over the element substrate and adjacent to the first electrode with the insulating layer interposed between the first electrode and the third electrode,
wherein the insulating layer covers an end of the third electrode,
wherein the second electrode is disposed over the third electrode with the organic layer interposed between the second electrode and the third electrode,
wherein the semiconductor device further comprises a reflection layer between the element substrate, and the first electrode and the third electrode in the cross section, and
wherein a film thickness of the insulating layer disposed between the reflection layer and the first electrode and a film thickness of the insulating layer disposed between the reflection layer and the third electrode are different from each other.

14. The semiconductor device according to claim 1, further comprising a microlens disposed over the second electrode,
wherein, in a planar view with respect to the lower surface of the first electrode, an apex of the microlens is included in the contact portion, and an angle of inclination of a surface of the microlens at a position overlapping an end portion on a contact portion side of the step portion in the planar view is greater than the angle of inclination of the surface of the microlens at a position overlapping an end portion of the contact portion in the planar view.

15. A display apparatus comprising:
a plurality of pixels, at least one of the plurality of pixels including the semiconductor device according to claim 1; and
a transistor electrically connected to the first electrode of the semiconductor device.

16. A photoelectric conversion apparatus comprising:
an optical unit including a plurality of lenses;
an imaging element configured to receive light having passed through the optical unit; and
a display unit configured to display an image captured by the imaging element,
wherein the display unit includes the semiconductor device according to claim 1.

17. An electronic device comprising:
a display unit including the semiconductor device according to claim 1;
a housing in which the display unit is disposed; and
a communication unit disposed in the housing and configured to communicate with the outside.

18. An illumination apparatus comprising:
a light source including the semiconductor device according to claim 1; and
a light diffusion unit or an optical film configured to allow light emitted from the light source to pass therethrough.

19. A movable object comprising:
a lamp fitting including the semiconductor device according to claim 1; and
a body in which the lamp fitting is provided.
